(19) United States
(12) Patent Application Publication
(10) Pub. No.: US 2025/0301587 A1
(43) Pub. Date: Sep. 25, 2025

(54) HOUSING AND ELECTRONIC DEVICE

(71) Applicant: Lenovo Enterprise Solutions (Singapore) Pte. Ltd., Singapore (SG)

(72) Inventors: Su-Jen TSAI, Singapore (SG); James LIEN, Singapore (SG); Meng-Ciao LYU, Singapore (SG); Tung Fu CHIEN, Singapore (SG); Chia Jou CHEN, Singapore (SG); Szu Ying CHEN, Singapore (SG)

(21) Appl. No.: 19/085,724

(22) Filed: Mar. 20, 2025

(30) Foreign Application Priority Data
Mar. 22, 2024 (CN) 202410339121.2

(51) Int. Cl. H05K 5/02

(52) U.S. Cl. CPC H05K 5/0226; H05K 5/0213; H05K 5/0221

(57) ABSTRACT

A housing includes a housing body and a movable assembly. The housing body includes an airflow channel extending along a first direction. The airflow channel includes an accommodation position for accommodating an electronic element. An air inlet of the airflow channel is formed on an end of the housing body along the first direction. A gap is formed on at least one side of the housing body parallel to the first direction. The movable assembly is arranged at the gap and includes at least one movable part. One movable part of the at least one movable part is connected to the housing body. The remaining movable parts of the at least one movable part are movably connected in sequence. At least some movable parts move toward or away from the housing body to change a flow area of the air inlet.

### CROSS-REFERENCE TO RELATED APPLICATION

The present disclosure claims priority to Chinese Patent Application No. 202410339121.2, filed on Mar. 22, 2024, the entire content of which is incorporated herein by reference.

### TECHNICAL FIELD

The present disclosure is related to the device heat dissipation field and, more particularly, to a housing and an electronic device.

### BACKGROUND

In electronic devices, electronic elements are typically arranged within a housing. The housing is designed with airflow channels that allow air to pass through and carry away heat from the electronic elements, thereby cooling down the electronic elements. However, in related technologies, the structure of the airflow channels formed at the housing is fixed, which is difficult to meet varying cooling requirements.

### SUMMARY

An aspect of the present disclosure provides a housing including a housing body and a movable assembly. The housing body includes an airflow channel extending along a first direction. The airflow channel includes an accommodation position for accommodating an electronic element. An air inlet of the airflow channel is formed on an end of the housing body along the first direction. A gap is formed on at least one side of the housing body parallel to the first direction. The movable assembly is arranged at the gap and includes at least one movable part. One movable part of the at least one movable part is connected to the housing body. The remaining movable parts of the at least one movable part are movably connected in sequence. At least some movable parts move toward or away from the housing body to change a flow area of the air inlet.

An aspect of the present disclosure provides an electronic device, including a housing, an electronic element, and an airflow generator. The housing includes a housing body and a movable assembly. The housing body includes an airflow channel extending along a first direction. The airflow channel includes an accommodation position for accommodating an electronic element. An air inlet of the airflow channel is formed on an end of the housing body along the first direction. A gap is formed on at least one side of the housing body parallel to the first direction. The movable assembly is arranged at the gap and includes at least one movable part. One movable part of the at least one movable part is connected to the housing body. The remaining movable parts of the at least one movable part are movably connected in sequence. At least some movable parts move toward or away from the housing body to change a flow area of the air inlet. The electronic element is arranged inside the airflow channel of the housing. An airflow generator is connected to the housing and configured to generate airflow within the airflow channel.

### BRIEF DESCRIPTION OF THE DRAWINGS

FIG. 1 is a schematic partial structural diagram of an electronic device according to some embodiments of the present disclosure.

FIG. 2 is a schematic structural diagram of an electronic device according to some embodiments of the present disclosure (with a movable assembly in a first state).

FIG. 3 is a schematic structural diagram of an electronic device according to some embodiments of the present disclosure (with a movable part in a second state).

FIG. 4 is a schematic structural diagram of an electronic device according to some embodiments of the present disclosure (with a movable part in a third state).

FIG. 5 is a schematic diagram showing a connection between a first movable part and a second movable part in a housing according to some embodiments of the present disclosure.

FIG. 6 is a schematic structural diagram of a telescopic part in a housing according to some embodiments of the present disclosure.

FIG. 7 is a schematic structural diagram of a drive part in a housing according to some embodiments of the present disclosure (with the drive part in an extended state).

FIG. 8 is a schematic structural diagram of a drive part in a housing according to some embodiments of the present disclosure (with the drive part in a retracted state).

FIG. 9 is a schematic structural diagram of an electronic device according to some embodiments of the present disclosure (on an air inlet side).

### REFERENCE NUMERALS

| | | |
|---|---|---|
| 100 Housing body | 110 Airflow channel | 111 Air inlet |
| 120 Gap | 200 Movable assembly | 210 Movable part |
| 21a Basic movable part | 21b First movable part | 21c Second movable |
| | | part |
| 220 Rotation shaft | 211 Connector | 212 Snap slot |
| 213 Notch | 214 First baffle | 215 Second baffle |
| 216 Clearance groove | 230 Telescopic part | 300 Drive part |
| 400 Electronic element | x First direction | y Second direction. |

### DETAILED DESCRIPTION OF THE EMBODIMENTS

To make the objectives, technical solutions, and advantages of embodiments of the present disclosure, the technical solutions of the present disclosure will be further described in detail below with reference to the accompanying drawings of embodiments of the present disclosure. The following embodiments are used to illustrate the present disclosure but are not intended to limit the scope of the present disclosure.

In embodiments of the present disclosure, the terms “first” and “second” are used for descriptive purposes only and should not be construed as indicating or implying relative importance or implicitly specifying the quantity of the indicated technical features. Thus, features defined by “first” or “second” can explicitly or implicitly include one or more of such features. In the description of embodiments of the present disclosure, unless otherwise specified, the term “a plurality of” means two or more.

Additionally, in embodiments of the present disclosure, directional terms such as “up,” “down,” “left,” and “right” are defined based on the orientation of the components as illustrated in the accompanying drawings. These directional terms are relative concepts and used for descriptive and clarifying purposes. The directional terms can change according to the change in the orientation of the components in the accompanying drawings.

In embodiments of the present disclosure, unless explicitly specified or limited otherwise, the term “connection” should be interpreted broadly. For example, “connection” may refer to a fixed connection, a detachable connection, or an integral connection. The “connection” can be a direct connection or an indirect connection through an intermediate medium.

In embodiments of the present disclosure, the terms “include,” “comprise,” or any other variation thereof are intended to cover non-exclusive inclusion, such that a process, method, article, or apparatus that includes a series of elements not only includes those elements but also includes other elements not explicitly listed or inherent to such process, method, article, or apparatus. When there is no further limitation, an element defined by the phrase “including a . . . ” does not exclude the presence of additional identical elements in the process, method, article, or apparatus that includes the element.

In embodiments of the present disclosure, terms such as “exemplary” or “for example” are used to provide examples, illustrations, or explanations. Any embodiment or design solution described as “exemplary” or “for example” in embodiments of the present disclosure should not be interpreted as being more preferred or advantageous over other embodiments or design solutions. The term such as “exemplary” or “for example” is intended to present related concepts in a specific manner.

Embodiments of the present disclosure provide an electronic device. The electronic device can include a computer, server, workstation, data center, industrial control machine, etc. The electronic device can typically include an electronic element, such as a central processing unit (CPU), graphics processing unit (GPU), and an information storage device. The electronic element can generate significant heat during operation. Thus, a suitable heat dissipation manner is needed for the electronic element to dissipate heat to allow the electronic element to operate at an appropriate environmental temperature.

In the electronic device, the electronic element can be arranged in the housing. The housing can include an airflow channel. The airflow can take away heat when passing through the electronic element to dissipate heat and reduce the temperature of the electronic element. In the related technology, the structure of the airflow channel formed at the housing can be fixed and cannot satisfy different heat dissipation needs simultaneously.

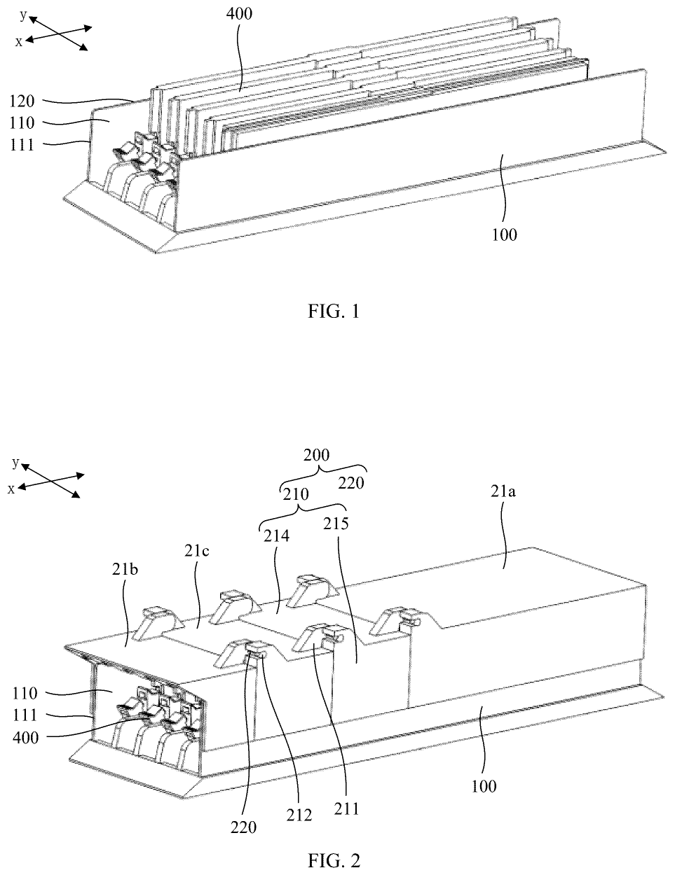

Thus, embodiments of the present disclosure further provide housing. As shown in FIGS. 1-3, the housing includes a housing body of 100 and a movable assembly of 200. The Housing body 100 includes an airflow channel 110 extending along a first direction x. The airflow channel 110 includes an accommodation position for accommodating an electronic element 400. The housing body 100 includes an air inlet 111 of the airflow channel 110 at an end in the first direction x. A gap of 120 is formed on at least a side of the housing body 100 in parallel with the first direction x. The movable assembly 210 is arranged at the gap 120. The movable assembly 200 includes at least one movable part 210. One movable part 210 of at least one movable part 210 is connected to the housing body 100, and the rest of the movable parts 210 are sequentially connected. At least some movable parts 210 can move to or away from the housing body 100 to change the flow area of the air inlet 111.

In embodiments of the present disclosure, the housing body 100 can include various structural forms. The housing body 100 can be block-shaped and column-shaped, such as a rectangular prism, cylinder, or other regular structures, or an irregular structure. For example, the housing body 100 can be a cuboid structure, and the first direction x can be a length direction, width direction, or height direction of the housing body 100.

Taking the first direction x as the length direction of the housing body 100 as an example, the air inlet 111 of the airflow channel 110 can be located at one end of the housing body 100 along the length direction of the housing body 100. The air inlet 111 can have a cuboid structure, and the flow area of the air inlet 111 can refer to the projection area of the air inlet 111 on the plane where the air inlet 111 is.

Based on this, the gap 120 can be formed at least on one side of the housing body 100 along the width direction or height direction of the housing body 100. The gap 120 can communicate with the air inlet 111. The gap 120 can extend to two ends of the housing body 100, or the gap 120 can be only arranged at one end of the housing body 100 having the air inlet 111. As shown in FIG. 1, in embodiments of the present disclosure, the gap 120 is formed at one end at the top of the housing body 100 and close to the air inlet 111. The gap 120 has a rectangular structure.

A plurality of surfaces of the housing body 100 parallel to the first direction x can include gaps 120. For example, two opposite surfaces of the housing body 100 parallel to the first direction x can each include a gap 120. For another example, two neighboring surfaces of the housing body 100 parallel to the first direction x can each include a gap 120. When a plurality of gaps 120 are provided, a plurality of movable assemblies 200 can be provided. The plurality of movable assemblies 200 can have an one-to-one correspondence with the plurality of gaps 120.

In embodiments of the present disclosure, the movable part 210 can have various structural forms. The movable part 210 can have a regular structural form, such as column-shaped, plate-shaped, and shell-shaped, or an irregular structural form. For example, the movable part 210 can include a plate-shaped structure parallel to the gap 120 where the movable part 210 is located. Thus, the movable part 210 can at least partially cover the corresponding gap 120 in a direction perpendicular to the surface where the gap 120 is.

In embodiments of the present disclosure, one movable part 210 of the movable parts 210 in the movable assembly 200 can be connected to the housing body 100. The movable part 210 can be referred to as a base movable part 21a. The connection between the base movable part 21a and the housing body 100 can be fixed, such as a snap-fit, adhesive, welding, threaded, or fastener connection, or movable, such as, a hinged, sliding or flexible connection. For example, the base movable part 21a can be fixedly connected to the housing body 100.

In embodiments of the present disclosure, the remaining movable parts 210 being sequentially and movably connected can include that, in a direction away from the housing body 100, the movable parts 210 can be connected end-to-end one by one with a movable connection manner. To facilitate description, the movable part 210 closer to the air inlet 111 of two neighboring movable parts 210 can be referred to as a first movable part 21b, while the movable part 210 farther from the air inlet 111 can be referred to as a second movable part 21c. The first movable part 21b and the second movable part 21c can be movably connected. The first movable part 21b can move toward or away from the housing body 100 relative to the second movable part 21c.

The movable part 210 moving toward or away from the housing body 100 can include that the movable part 210 can at least move away from a center axis of the housing body in the first direction x at least along a direction. For example, the movable part 210 can move away from or toward the housing body along the direction perpendicular to the plane where the gap 120 is located to increase or reduce the flow area of the air inlet 111.

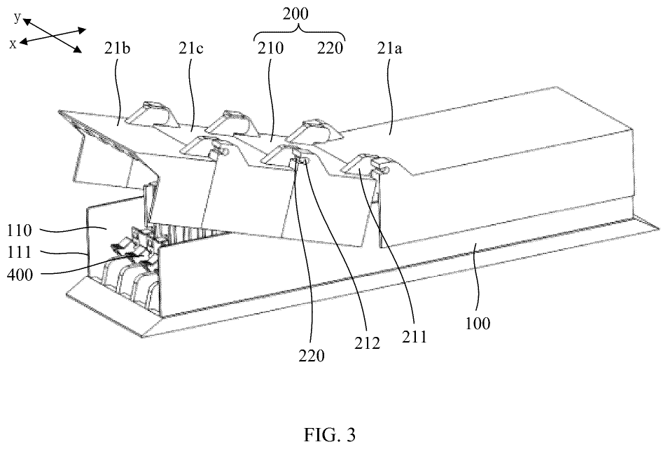

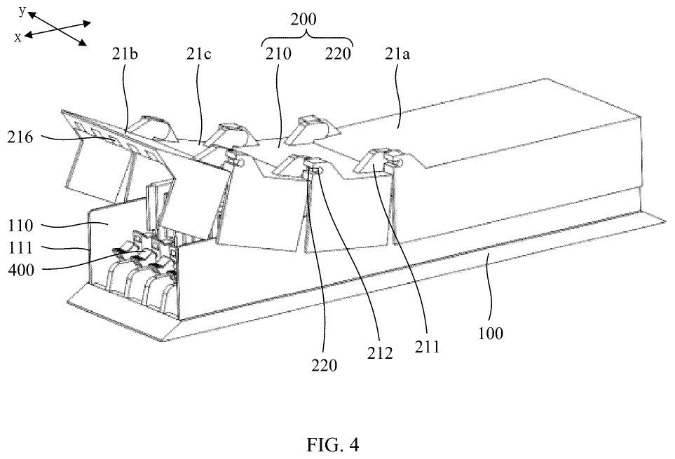

In embodiments of the present disclosure, when the movable assembly 200 adjusts the flow area of the air inlet 111, the movable assembly 200 can have a plurality of states. For example, only the movable part 210 close to the air inlet 111 can move toward or away from the housing body 100. As shown in FIG. 3, in some embodiments, the base movable part 21a moves relative to the housing body 100 and drives other movable parts 210 to move toward or away from the housing body 100. As shown in FIG. 4, in other embodiments, the movable part 210 moves toward or away from the housing body 100 relative to the movable part 210 connected to the movable part 210.

In the housing of embodiments of the present disclosure, the housing body 100 can protect the electronic element 400 and include the airflow channel 110. The electronic element 400 can be arranged in the accommodation position in the airflow channel 110. The airflow channel 110 can extend along the first direction x. An air inlet 111 of the airflow channel 110 can be formed at an end of the housing body along the first direction x. The airflow can enter the airflow channel 110 through the air inlet 111 to pass through the electronic element in the accommodation position to take away the heat of the electronic element 400 to dissipate heat and reduce temperature.

Based on this, a gap 120 can be formed at least on a side of the housing body 100 parallel to the first direction x. The movable assembly 200 can be arranged at the gap 120. The movable assembly 200 can include at least one movable part 210. One movable part 210 of the at least one movable part 210 can be connected to the housing body 100, and the other movable parts 210 can be sequentially and movably connected. At least some movable parts 210 can move toward or away from the housing body 100 to adjust the flow area of the air inlet 111. In some embodiments, the movable parts 210 can move away from the housing body 100 to increase the flow area of the air inlet 111 to allow more airflow to enter the airflow channel 110 to take away the heat of the electronic element 400 faster, which is suitable for the situation that the electronic element 400 generates a relatively large amount of heat. On the contrary, the movable part 210 can move toward the housing body 100 to reduce the flow area of the air inlet 111, which is suitable for the situation that the electronic element 400 generates a relatively small amount of heat. The airflow can be better converged in the narrow airflow channel 110 and can better absorb the heat.

In the related technology, compared to the solution of the air inlet 111 of the airflow channel with the fixed structure, in the housing of embodiments of the present disclosure, the movable assembly 200 can be arranged at the housing body 100, by changing the form of the movable assembly 200, the flow area of the air inlet 111 of the airflow channel 110 can be adjusted conveniently to adapt to different heat dissipation needs.

In the present disclosure, the movable connection method of the neighboring two movable parts 210 is not limited. Any connection method, in which the two neighboring movable parts 210 can move relatively can be within the scope of the present disclosure, such as, a rotation connection, a sliding connection, and a flexible connection.

As shown in FIGS. 2-4, in embodiments of the present disclosure, the two neighboring movable parts 210 are hinged. The hinge axis of the two neighboring movable parts 210 can be parallel to the first direction x, or perpendicular to the first direction x and parallel to the plane of the corresponding gap 120. The hinged configuration is simple in structure, provides positioning, and makes the movement of the movable parts 210 easier to control.

In some other embodiments of the present disclosure, the movable assembly 200 can also include a flexible element, and two neighboring movable parts 210 can be connected through the flexible element. The flexible element can include soft rubber, fabric, chains, etc. The flexible element can be configured to cause the two neighboring movable parts 210 to have higher degrees of freedom. Thus, the movement direction can be more flexible.

The two neighboring movable parts 210 may need to be relatively positioned to cause the flow area of the air inlet 111 to be maintained at a suitable size. As shown in FIGS. 4-6, in some embodiments, the movable part 210 includes a rotation shaft 220. The two neighboring movable parts 210 can be hinged through the rotation shaft 220.

Based on this, the rotation shaft 220 can be a damping rotation shaft. A damping rotation shaft can be an apparatus configured to allow two parts to rotate relatively through friction and be positioned at any angle to realize the suspension of the two neighboring movable parts 210. Due to the impact of gravity, the damping rotation shaft away from the air inlet 111 may need a damping greater than a damping needed by the damping rotation shaft close to the air inlet 111. The damping rotation shaft can be configured to realize the relative position of the movable parts 210, which has a simple structure and is easy to implement.

In some other embodiments of the present disclosure, the housing can also include a lock assembly. The lock assembly can be configured to lock or unlock the movable assembly 200 relative to the housing body 100. Of course, the damping rotation shaft and the lock assembly can be arranged together. With the cooperation between the damping rotation shaft and the lock assembly, the operation can be more convenient.

In embodiments of the present disclosure, the lock assembly can include a snap-fit part. A connector can be connected to the first movable part 21b and rotate with the first movable part 21b relative to the second movable part 21c. The second movable part 21c can include a plurality of snap-fit slots. When the first movable part 21b rotates relative to the second movable part 21c to different angles, the snap-fit part can be aligned with different snap-fit slots. The snap-fit part can be extended axially along the rotation shaft 220 into the aligned snap-fit slot, thereby locking the corresponding neighboring movable parts 210. When the snap-fit part is retracted from the snap-fit slot, the corresponding neighboring movable parts 210 can be unlocked.

To facilitate the hinged connection between two neighboring movable parts 210, as shown in FIGS. 4-6, in some embodiments of the present disclosure, one movable part 210 of the two neighboring movable parts 210 is connected to a rotation shaft 220, and the other one includes a snap-fit slot 212. The rotation shaft 220 is rotatably connected within the snap-fit slot 212 and can pass through the notch 213 of the snap-fit slot 212 along the radial direction of the rotation shaft.

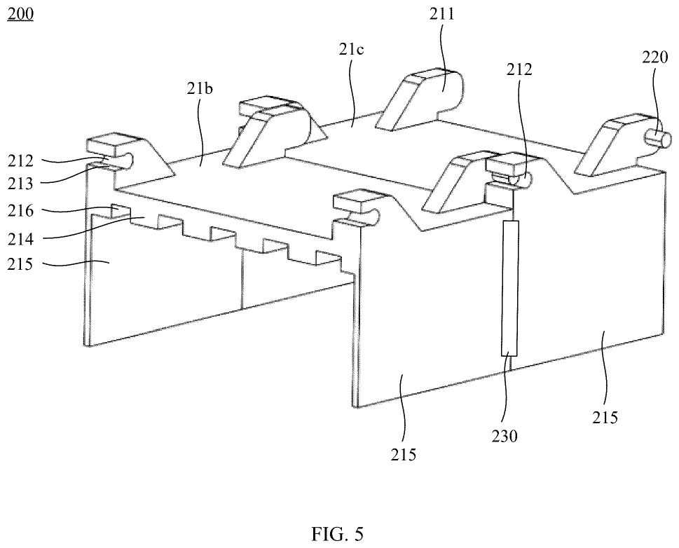

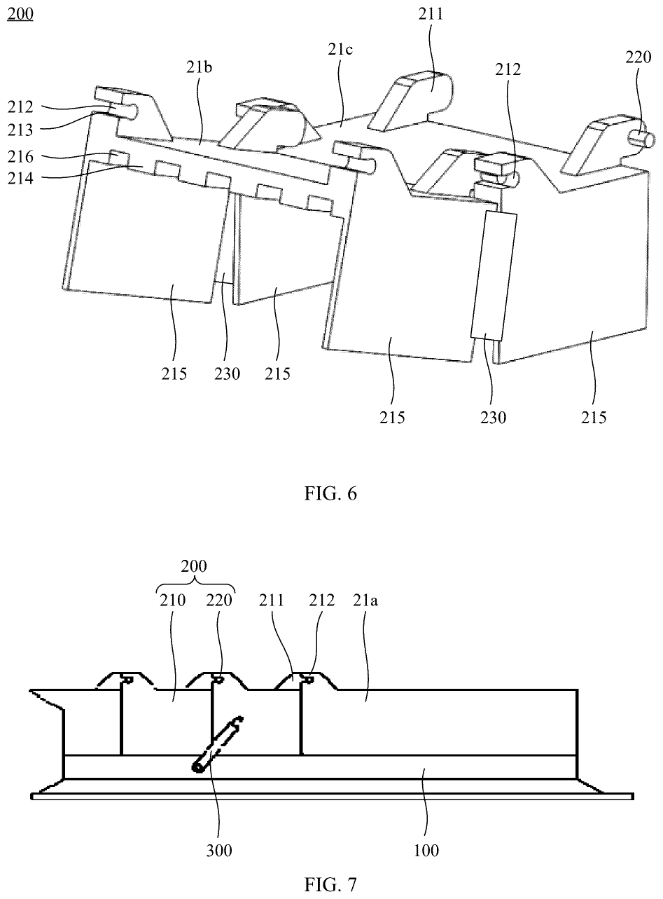

In embodiments of the present disclosure, the movable part 210 of the two neighboring movable parts 210 closer to the air inlet 111 can include a snap-fit slot 212, while the other movable part 210 can include the rotation shaft 220. Alternatively, the movable part 210 of the two neighboring movable parts 210 closer to the air inlet 111 can be connected to the rotation shaft 220, while the other movable part 210 can include the snap-fit slot 212. As shown in FIGS. 5 and 6, in some embodiments of the present disclosure, the rotation shaft 220 is arranged at the first movable part 21b, and the snap-fit slot 212 is formed at the second movable part 21c.

In embodiments of the present disclosure, the movable part 210 can include a plate-shaped structure parallel to the corresponding gap 120. The rotation shaft 220 can be connected to the surface of the plate-shaped structure or pass through the plate-shaped structure. To make the rotation of the two neighboring movable parts 210 more flexible, as shown in FIGS. 5 and 6, in some embodiments of the present disclosure, a connector 211 is arranged on the side of the movable part 210 away from the housing body 100. The rotation shaft 220 and the snap-fit slot 212 are correspondingly arranged at the connector 211.

In embodiments of the present disclosure, the connector 211 can include a plurality of structures. The connector 211 can have a regular structure, such as a block-shaped, plate-shaped, rod-shaped, or an irregular structure. As shown in FIGS. 5 and 6, in embodiments of the present disclosure, the connector 211 is a plate-shaped structure. The connector 211 bends and extends in a direction away from the center of the movable part 210 to be connected to the neighboring movable part 210.

The two neighboring movable parts 210 can be connected through one or a plurality of sets of connectors 211. One set of connectors 211 can include two connectors 211 respectively arranged on the two movable parts 210. One connector 211 can include the rotation shaft 220, and the other connector can include the snap-fit slot 212. The plurality of sets of connectors 211 can be distributed along the axial direction of the corresponding rotation shaft 220. For example, two sets of connectors 211 can be provided and arranged on two sides of the plate-shaped structure along the axial direction of the rotation shaft 220 to ensure more balanced force distribution on the movable part 210.

In embodiments of the present disclosure, the rotation shaft 220 can be rotationally connected within the snap-fit slot 212 and can pass through the notch 213 of the snap-fit slot 212 along the radial direction of the rotation shaft 220. In some embodiments, the radial size of the snap-fit slot 212 can be larger than the radial size of the rotation shaft 220 to allow the rotation shaft 220 to rotate relative to the snap-fit slot 212. The size of the notch 213 can be smaller than the radial size of the rotation shaft 220 to limit the position of the rotation shaft 220 to lower the possibility for the rotation shaft 220 disengaging from the position-limiting groove. The connector 211 can be made of plastic rubber. Thus, the connector 211 can deform at the position corresponding to the notch 213 under an external force. After the rotation shaft 220 enters the snap-fit slot 212, the notch 213 can restore to the original shape under an elastic force to limit the position of the rotation shaft 220.

The housing of embodiments of the present disclosure can include the snap-fit slot 212 at the movable part 210. The rotation shaft 220 can be rotatably connected within the snap-fit slot 212 to allow the rotation shaft 220 to rotate relative to the snap-fit slot 212. Meanwhile, the notch 213 of the snap-fit slot 212 can allow the rotation shaft 220 to pass through to facilitate the rotation shaft 220 to be mounted at the corresponding snap-fit slot 212, which has a simple structure and is easy to assemble and disassemble.

As shown in FIGS. 2-5, in some embodiments of the present disclosure, the movable part 210 includes a first baffle 214 and a second baffle 215. The second baffle 215 is connected to at least one side of the first baffle 214 along the second direction y. The second baffle 215 is parallel to the first direction x. The second direction y and the first direction x have an angle. The second baffle 215 and the housing body 100 at least partially overlap along the second direction y.

In embodiments of the present disclosure, the first baffle 214 can be arranged parallel to the plane of the gap 120. The connector 211 is located on the side of the first baffle 214 away from the housing body 100. The first baffle 214 can cover the gap 120. When the first baffle 214 moves away from the housing body 100, a gap can exist between the first baffle 214 and the housing body 100. Therefore, the second baffle 215 is provided.

In embodiments of the present disclosure, the second baffle 215 can be connected to the first baffle 214 and is arranged on at least one side of the first baffle 214 along the second direction y. When the movable part 210 moves away from the housing body 100, the second baffle 215 and the housing body 100 can at least partially overlap along the second direction y to cover the gap between the first baffle 214 and the housing body 100 to reduce the possibility of airflow escaping from the airflow channel 110.

In embodiments of the present disclosure, the angle between the first direction x and the second direction y can be acute, obtuse, or right-angled. The first baffle 214 can include one or a plurality of second baffles 215. As shown in FIGS. 1-3, in some embodiments of the present disclosure, the second direction y is parallel to the planes of the air inlet 111 and the gap 120, and the first direction x and the second direction y are perpendicular. The first baffle 214 and the second baffle 215 are perpendicular to each other, and a second baffle 214 is arranged on each of the two sides of the first baffles 215 along the second direction y.

In embodiments of the present disclosure, the second baffle 215 can be arranged at the inner or outer side of the housing body 100. To facilitate the position of the movable assembly 200 to be limited, as shown in FIGS. 2 and 3, in embodiments of the present disclosure, the second baffle 215 is arranged on the outer side of the housing body 100.

In embodiments of the present disclosure, the first baffle 214 and the second baffle 215 can be connected through snap-fit, adhesive, welding, fasteners, etc. For example, the first baffle 214 and the second baffle 215 can be integrally formed to make the movable part 210 to form a ⊏ shaped structure that can be relatively clamped onto the housing body 100.

When the first baffles 214 of two neighboring movable parts 210 are parallel to each other, a first plate and a second plate of the two movable parts 210 can abut against each other to limit the position to allow the first movable part 21b only to move away from the housing body 100 relative to the second movable part 21c to limit the position between the two neighboring movable parts 210. When only one movable part 210 moves away from the housing body 100, all the movable parts 210 at the free end of the movable part 210 can be driven to move away from the housing body 100. The free end of the movable part 210 can refer to the end of the movable part 210 close to the air inlet 111.

To further reduce the possibility of airflow escaping from the airflow channel 110, in some embodiments of the present disclosure, the second baffles 215 of the two neighboring movable parts 210 can at least partially overlap along the second direction y. Thus, the second baffles 215 of the two neighboring movable parts 210 can be staggered along the second direction y to allow the second baffles 215 to move relatively.

As shown in FIGS. 5 and 6, in some other embodiments of the present disclosure, the movable assembly 200 also includes a telescopic part 230. The second baffles 215 of two neighboring movable parts 210 are connected through the telescopic part 230. The second baffles 215 on the same side of the first baffle 214 are connected through the telescopic part 230, and the second baffles 215 on the two sides of the first baffle 214 are connected through the corresponding telescopic part 230. To facilitate description, the following explanation is made by taking the second baffles 215 on the same side of the first baffle 214 as an example.

The telescopic part 230 can include a foldable bellows, a windproof curtain, etc. When the first movable part 21b of two neighboring movable parts 210 moves away from the housing body 100, a gap can appear between the second baffles 215 of the two movable parts 210. Then, the telescopic part 230 can be stretched to cover the gap. On the contrary, when the first movable part 21b of the two neighboring movable parts 210 moves toward the housing body 100, the gap between the two second baffles 215 can be reduced to compress the telescopic part 230 to allow the movable part 210 to move relatively.

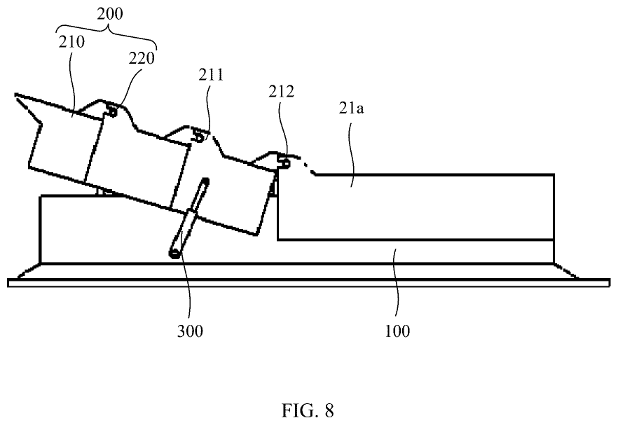

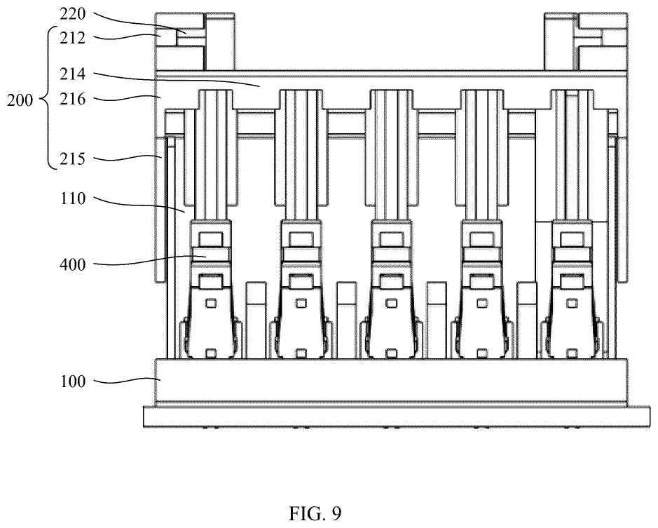

The movement of the movable assembly 200 can be manually operated by an operator or driven by a drive mechanism. As shown in FIGS. 7 and 8, in some embodiments of the present disclosure, the housing further includes a drive part 300. The drive part 300 is connected to the housing body 100. The output shaft of the drive part 300 is connected to the movable part 210 to drive the corresponding movable part 210 to move relative to the housing body 100.

In embodiments of the present disclosure, the drive part 300 can include a drive part 300 configured to output a rotation power, such as a rotary cylinder or motor, or a drive part 300 configured to output a linear power such as a cylinder, hydraulic cylinder, or electric telescopic rod. The drive part 300 can be connected to the corresponding movable part 210 through hinges, sliding connections, or transmission connections through gear assemblies, worm gear assemblies, gear rack assemblies, or belt drive assemblies, which are not limited here.

In embodiments of the present disclosure, the output shaft of the drive part 300 can be connected to the base movable part 21a, the movable part 210 of the movable assembly 200 close to the air inlet 111, or one or a plurality of the other movable parts 210. For example, the drive part 300 can be hinged to the housing body 100, and the output shaft of the drive part 300 can be hinged to the movable part 210 at the air inlet 111. When the drive part 300 extends, the movable parts 210 of the movable assembly 200 can be driven to move away from the housing body 100. When the drive part 300 retracts, the movable parts 210 of the movable assembly 200 can be driven to move toward the housing body 100.

In embodiments of the present disclosure, the drive part 300 can also be arranged between two neighboring movable parts 210 instead of on the housing body 100. For example, the drive part 300 can be hinged to the second baffle 215 of the second movable part 21c, and the output shaft of the drive part 300 can be hinged to the corresponding second baffle 215 of the first movable part 21b. The hinge axis of the drive part 300 can be parallel to the rotation shaft 220. The drive part 300 can be a cylinder. When the drive part 300 extends, the first movable part 21b can be driven to move away from the housing body 100 relative to the second movable part 21c. When the drive part 300 retracts, the first movable part 21b can be driven to move toward the housing body 100 relative to the second movable part 21c.

One or a plurality of airflow channels 110 can be arranged in the housing body 100. The plurality of airflow channels 110 can be arranged at an interval or can communicate with each other. In some embodiments of the present disclosure, a plurality of airflow channels 110, can be provided. Each airflow channel 110 can include a movable assembly 200. Thus, the flow area of the air inlet 111 can be independently adjusted for each airflow channel 110 to make the adjustment more flexible.

As shown in FIG. 9, in some other embodiments of the present disclosure, the movable assembly 200 extends along the second direction y to the two sides of the gap 120 to cover the plurality of airflow channels 110. The second direction y and the first direction x have an angle. Thus, the plurality of airflow channels 110 can be adjusted at one time to make the adjustment simpler.

As shown in FIGS. 6 and 9, in some embodiments of the present disclosure, a clearance groove 216 is arranged at a position of the movable part 210 corresponding to each accommodation position. The clearance groove 216 is configured to avoid the electronic element 400. The accommodation space can be configured to avoid the electronic element 400 at the corresponding position. Thus, when the movable assembly 200 covers the gap 120, the structure can be tighter, and the space occupied by the housing can be reduced, which can be beneficial for the miniaturization of the housing.

For example, in some embodiments of the present disclosure, the electronic device can include the housing, the electronic element 400, and an airflow generator. The electronic element 400 can be arranged inside the airflow channel 110 of the housing. The airflow generator can be connected to the housing. The airflow generator can be configured to generate airflow flowing inside the airflow channel 110.

In embodiments of the present disclosure, the airflow generator can include a vortex fan, axial fan, etc. The airflow generator can be arranged inside the housing body 100, i.e., within the airflow channel 110, or outside the housing body 100. Additionally, the airflow generator can be arranged at the air inlet 111 of the airflow channel 110 or an air outlet of the airflow channel 110, which is not limited here.

As shown in FIGS. 1-4, in embodiments of the present disclosure, the plurality of airflow channels 110 that communicate with each other are formed in the housing body 100 of the housing and share an air inlet 111. An electronic element 400 is arranged in each airflow channel 110. A gap 120 is formed on an upper side of the housing body 100. The gap 120 extends to the two ends of the housing body 100 along the first direction x and communicates with the air inlet 111. The movable assembly 200 covers the plurality of airflow channels 110. The movable assembly 200 includes a base movable part 21a fixedly connected to the housing body 100. A plurality of movable parts 210 are sequentially hinged through the rotation shafts 220 along the direction, in which the base movable part 21a faces the air inlet 111. The plurality of movable parts 210 can achieve suspension through damping rotation shafts. When at least some movable parts of the plurality of movable parts 210 move away from the housing body 100, the flow area of the air inlet 111 can be increased to allow more airflow to enter the housing body 100. On the contrary, when the movable parts 210 move toward the housing body 100, the flow area of the air inlet 111 can be reduced to reduce the space occupied and converge the airflow.

The sequence numbers of embodiments of the present disclosure can be for illustration and do not represent the superiority or inferiority of embodiments of the present disclosure. The above are merely some embodiments of the present disclosure and do not limit the scope of the present disclosure. Equivalent structures or equivalent process transformations based on the content of the present disclosure and accompanying drawings that are directly or indirectly applied in other related technical fields are within the scope of the present disclosure.

What is claimed is:

1. A housing comprising:
a housing body including an airflow channel extending along a first direction, the airflow channel including an accommodation position for accommodating an electronic element, an air inlet of the airflow channel being formed on an end of the housing body along the first direction, and a gap being formed on at least one side of the housing body parallel to the first direction; and
a movable assembly arranged at the gap and including at least one movable part, one movable part of the at least one movable part being connected to the housing body, the remaining movable parts of the at least one movable part being movably connected in sequence, and at least some movable parts moving toward or away from the housing body to change a flow area of the air inlet.

2. The housing according to claim 1, wherein:
two neighboring movable parts are hinged; or
the movable assembly further includes a flexible part, and the two neighboring movable parts are connected through the flexible part.

3. The housing according to claim 2,
wherein the movable part further includes a rotation shaft, the two neighboring movable parts are hinged through the rotation shaft, and the rotation shaft is a damping rotation shaft; and/or
the housing further including a lock assembly configured to lock or unlock the movable assembly relative to the housing body.

4. The housing according to claim 3, wherein:
one movable part of the two neighboring movable parts is connected to the rotation shaft;
the other one movable part of the two neighboring movable parts includes a snap-fit slot; and
the rotation shaft is connected inside the snap-fit slot and passes through a notch of the snap-fit slot.

5. The housing according to claim 1, wherein:
the movable part includes a first baffle and a second baffle;
the second baffle is connected to at least one side of the first baffle along a second direction and parallel to the first direction;
the second direction and the first direction have an angle; and
the second baffle and the housing overlap at least partially along the second direction.

6. The housing according to claim 5, wherein:
the second baffles of the two neighboring movable parts overlap at least partially along the second direction; or
the movable assembly further includes a telescopic part, and the second baffles of the two neighboring movable parts are connected through the telescopic part.

7. The housing according to claim 1, further comprising:
a drive part connected to the housing body;
wherein an output shaft of the drive part is configured to transmission connect the movable part to drive the corresponding movable part to move relative to the housing.

8. The housing according to claim 1, wherein:
a plurality of airflow channels are provided, each airflow channel includes the movable assembly, or the movable assembly extends along the second direction to two sides of the gap to cover the plurality of airflow channels; and
the second direction and the first direction have an angle.

9. The housing according to claim 8, wherein a clearance groove corresponding to each accommodation position is arranged at the movable part and is configured to avoid the electronic element.

10. An electronic device, comprising:
a housing including:
a housing body including an airflow channel extending along a first direction, the airflow channel including an accommodation position for accommodating an electronic element, an air inlet of the airflow channel being formed on an end of the housing body along the first direction, and a gap being formed on at least one side of the housing body parallel to the first direction; and
a movable assembly arranged at the gap and including at least one movable part, one movable part of the at least one movable part being connected to the housing body, the remaining movable parts of the at least one movable part being movably connected in sequence, and at least some movable parts moving toward or away from the housing body to change a flow area of the air inlet;
the electronic element arranged inside the airflow channel of the housing; and
an airflow generator connected to the housing and configured to generate airflow within the airflow channel.

11. The device according to claim 10, wherein:
two neighboring movable parts are hinged; or
the movable assembly further includes a flexible part, and the two neighboring movable parts are connected through the flexible part.

12. The device according to claim 11, wherein:
the movable part further includes a rotation shaft, the two neighboring movable parts are hinged through the rotation shaft, and the rotation shaft is a damping rotation shaft; and/or
the housing further includes a lock assembly configured to lock or unlock the movable assembly relative to the housing body.

13. The device according to claim 12, wherein:
one movable part of the two neighboring movable parts is connected to the rotation shaft;
the other one movable part of the two neighboring movable parts includes a snap-fit slot; and
the rotation shaft is connected inside the snap-fit slot and passes through a notch of the snap-fit slot.

14. The device according to claim 10, wherein:
the movable part includes a first baffle and a second baffle;
the second baffle is connected to at least one side of the first baffle along a second direction and parallel to the first direction;
the second direction and the first direction have an angle; and
the second baffle and the housing overlap at least partially along the second direction.

15. The device according to claim 14, wherein:
the second baffles of the two neighboring movable parts overlap at least partially along the second direction; or
the movable assembly further includes a telescopic part, and the second baffles of the two neighboring movable parts are connected through the telescopic part.

16. The device according to claim 10, wherein:
the housing further includes a drive part connected to the housing body; and
an output shaft of the drive part is configured to transmission connect the movable part to drive the corresponding movable part to move relative to the housing.

17. The device according to claim 10, wherein:
a plurality of airflow channels are provided, each airflow channel includes the movable assembly, or the movable assembly extends along the second direction to two sides of the gap to cover the plurality of airflow channels; and
the second direction and the first direction have an angle.

18. The device according to claim 17, wherein a clearance groove corresponding to each accommodation position is arranged at the movable part and is configured to avoid the electronic element.
